(19) United States
(12) Patent Application Publication
(10) Pub. No.: US 2024/0405730 A1
(43) Pub. Date: Dec. 5, 2024

(54) SWITCHED CAPACITORS TO GALVANICALLY ISOLATE AND AMPLIFY ANALOG SIGNALS VIA TRANSFERRED DIFFERENTIAL VOLTAGE SIGNAL

(71) Applicant: Microchip Technology Incorporated, Chandler, AZ (US)

(72) Inventors: Gerald Steele, Chandler, AZ (US); David Gammie, Chandler, AZ (US); Dong Wang, Chandler, AZ (US)

(73) Assignee: Microchip Technology Incorporated, Chandler, AZ (US)

(21) Appl. No.: 18/658,240

(22) Filed: May 8, 2024

Related U.S. Application Data
(60) Provisional application No. 63/469,843, filed on May 31, 2023.

(51) Int. Cl. H03F 3/00

(52) U.S. Cl. CPC H03F 3/005; H03F 2200/451

(57) ABSTRACT

Integrated circuits and methods to provide an operative coupling comprising an input stage and an output stage between an analog input and an analog output; synchronously operate a plurality of high voltage domain switches of the input stage and a plurality of low voltage domain switches of the output stage at a frequency to galvanically isolate the input stage from the output stage across a plurality of capacitors having a plurality of input plates respectively connected to the switches of the input and output stages; supply an analog input signal to the input stage; transfer a differential voltage signal component within a range of a common mode voltage supply from the high voltage domain of the input stage to the low voltage domain of the output stage; differentially amplify the low voltage domain differential voltage signal component; and output an analog output signal.

### PRIORITY

This application claims priority to U.S. Provisional Patent Application No. 63/469,843, filed May 31, 2023, the contents of which are hereby incorporated in their entirety.

### TECHNICAL FIELD

The present disclosure relates to analog signal isolation and sensing, in particular, to switched capacitors to galvanically isolate and amplify analog signals via transferred differential voltage signals.

### BACKGROUND

Many electrical measurements are made on systems that cannot be electrically connected via direct wiring to the measurement system. Devices are used that isolate the input signal from the output signal using any of several methods of passing electronic signals through an isolation barrier.

An isolation amplifier is an amplifier that is galvanically isolated between its input and output circuits, including their associated power supplies. Previous devices termed isolation amplifiers have had a complex companion isolated power supply to provide power to the isolation side of the circuit. Isolation amplifiers typically have separate bulky and expensive power for their isolated input state. Some devices are available that integrate the input power supply into a single package with the amplifier. But the power circuitry is complex and expensive because isolation is across a digital barrier having modulation and demodulation complexity and an isolating power supply. These systems may convert the input analog signal to a digital signal and then convert the signal back to an analog signal via analog-to-digital converters (ADC) and digital-to-analog converters (DAC) powered by transformers. Alternatively, optical isolation products use optocouplers to directly couple analog signals so that they are not converted to a digital signal. However, optical isolation products may not provide desirable offset, linearity, and drift characteristics.

There is a need for integrated circuits and methods to isolate an input analog signal from output analog signal in insolation amplifiers of electrical measurement systems.

### SUMMARY OF THE INVENTION

According to aspects, there is provided integrated circuits and methods to switch capacitors to galvanically isolate and amplify analog signals via transferred differential voltage signal components. Isolation amplification may be provided for an analog signal without analog-to-digital conversion of the signal and without an isolated power supply for the isolation side of the circuit. An isolation amplifier may have an output stage with an integrated power supply.

Aspects provide a method comprising: providing an operative coupling comprising an input stage and an output stage between an analog input and an analog output; synchronously operating a plurality of high voltage domain switches of the input stage and a plurality of low voltage domain switches of the output stage at a frequency to galvanically isolate the input stage from the output stage across a plurality of capacitors having a plurality of input plates respectively connected to the plurality of switches of the input stage and a plurality of output plates respectively connected to the plurality of switches of the output stage; supplying an analog input signal to the input stage; transferring a differential voltage signal component within a range of a common mode voltage supply from the high voltage domain of the input stage to the low voltage domain of the output stage; differentially amplifying the low voltage domain differential voltage signal component; and outputting an analog output signal.

According to an aspect, there is provided a monolithic integrated circuit comprising: input terminals to receive an analog input signal; an operative coupling comprising: an input stage coupled to the input terminals and comprising a plurality of high voltage domain switches; an output stage comprising a plurality of low voltage domain switches and a voltage common mode power source; a galvanic isolation barrier between the input stage and the output stage comprising: a plurality of capacitors having a plurality of input plates respectively connected to the plurality of high voltage domain switches and a plurality of output plates respectively connected to the plurality of low voltage domain switches; and a controller to synchronously operate the plurality of input switches and the plurality of output switches at a frequency to charge respective ones of the plurality of capacitors to a voltage; wherein the operative coupling is to transfer a differential voltage signal component from a high voltage domain to a low voltage domain; a differential amplification circuit coupled to the output stage of the operative coupling; and output terminals coupled to the differential amplification circuit to output an analog output signal.

An aspect provides a monolithic integrated circuit comprising: input terminals to receive an analog input signal; an operative coupling comprising: an input stage coupled to the input terminals and comprising a plurality of high voltage domain switches; an output stage comprising a plurality of low voltage domain switches and a voltage common mode power source; a galvanic isolation barrier between the input stage and the output stage comprising: a plurality of capacitors having a plurality of input plates respectively connected to the plurality of high voltage domain switches and a plurality of output plates respectively connected to the plurality of low voltage domain switches; and a controller to synchronously operate the plurality of input switches and the plurality of output switches at a frequency to galvanically isolate the input stage from the output stage and to transfer a differential voltage signal component within a range of a common mode voltage supply from the high voltage domain to the low voltage domain; a differential amplification circuit coupled to the output stage of the operative coupling; and output terminals coupled to the differential amplification circuit to output an analog output signal.

### BRIEF DESCRIPTION OF THE DRAWINGS

The figures illustrate examples of methods and integrated circuits to switch capacitors to galvanically isolate and amplify analog signals via transferred differential voltage signal components. Methods and integrated circuits may be for isolation amplification of an analog signal without analog-to-digital conversion of the signal and without isolated power being supplied to an isolation side of a circuit.

FIG. 1 is a schematic diagram depicting an apparatus 100 to amplify differential voltage signal components of a voltage across a resistor.

FIG. 2 is a schematic diagram of an operative coupling.

FIG. 3 is a schematic diagram depicting a differential amplification circuit.

FIG. 4 shows a schematic diagram of an isolation amplifier circuit having an operative coupling with an input stage and an output stage, and a differential amplification circuit.

FIG. 5 shows an enlarged view of the operative coupling with an input stage and an output stage shown in FIG. 4.

FIG. 6 shows a schematic diagram of a high-voltage level shifter.

FIGS. 7A-7F show schematic diagrams of the high-voltage level shifter shown in FIG. 6, wherein generated clock signals drive the input switches at their relative common modes.

FIG. 8 shows a graph of voltage across time indicating that the switched capacitors provide isolation, wherein a differential voltage is transferred to a low voltage domain (while still maintaining the differential value).

FIG. 9 shows a flow chart of a method for switching capacitors to galvanically isolate and amplify analog signals via transferred differential voltage signal components.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect, there is provided a circuit for isolated analog sensing with no additional power supplied on the isolation side of the circuit. The circuit may have a switched capacitor input to provide galvanic isolation of analog signals without isolated power being supplied to the isolation side of the circuit. A circuit, which may be provided as an integrated circuit, may provide accurate and economical shunt current sensing for high voltage systems e.g., up to +/−1000 volts of isolation. The integrated circuit may be a monolithic galvanic isolation amplifier with +/−1000 volts common-mode capability (CMC) with applications in current sensing and industrial sensing. A monolithic integrated circuit is a complete circuit or group of circuits manufactured in a single piece of silicon. The monolithic galvanic isolation amplifier may be self-contained because no power is supplied to the isolation side of the circuit. Galvanic isolation may provide a DC isolation barrier while the wanted signal is sent across the barrier, thus providing an open circuit for direct current (DC) and a low impedance path for alternating current (AC), with level translation for the signal provided through passive elements (capacitor)). The input terminals may have no direct electrical connection to the output terminals. In particular, a monolithic galvanic isolation amplifier may have input terminals with no direct electrical connection to the output terminals, wherein a signal may be transferred from input terminals through switched capacitors to output terminals. While it may be considered an indirect connection through a passive device, like a capacitor, the output terminals are isolated from the input terminals while a differential voltage signal component is transferred from the input terminals to the output terminals.

The circuit achieves isolation through isolation barriers naturally occurring in capacitors on monolithic integrated circuits.

United States Patent Application Publication Number 2022/0376666, published on Nov. 24, 2022, is incorporated herein by reference in its entirety and for all purposes.

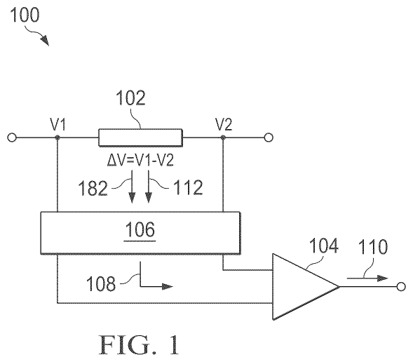

FIG. 1 is a schematic diagram depicting an apparatus 100 to amplify differential voltage signal components of a voltage across a resistor. An amplified differential voltage signal component may be utilized in a differential current sensing topology.

Apparatus 100 includes a resistor 102, a differential amplification circuit 104, and an operative coupling 106. Differential amplification circuit 104 and resistor 102 are coupled to amplify a differential voltage signal component 108 of a voltage across resistor 102 (voltage ΔV). The voltage across resistor 102 is a difference between a voltage at a first end of resistor 102 (voltage V1) and a voltage at a second end of resistor 102 (voltage V2). Voltages V1 and V2 may respectively include a common mode voltage signal component 112, e.g., a common mode voltage (VCM).

Operative coupling 106 is between resistor 102 and differential amplification circuit 104 to pass differential voltage signal component 108 and isolate common mode voltage signal component 112 of the voltage ΔV across the resistor 102. More specifically, operative coupling 106 operates to provide V1-VCM to a first input terminal of differential amplification circuit 104 and provide V2-VCM to a second input terminal of differential amplification circuit 104. Optionally, operative coupling 106 may operate to provide a controlled common mode voltage (VCCM) to first and second input terminals of differential amplification circuit 104 together with voltages V2-VCM and V1-VCM, as discussed below.

In one or more examples, operative coupling 106 operates to pass differential voltage signal component 108 and isolate common mode voltage signal component 112 of the voltage ΔV via multiple integration and transfer phases performed at least partially responsive to a control signal (control signal not depicted). Differential amplification circuit 104 amplifies the differential voltage signal component 108 to generate amplified differential voltage signal component 110.

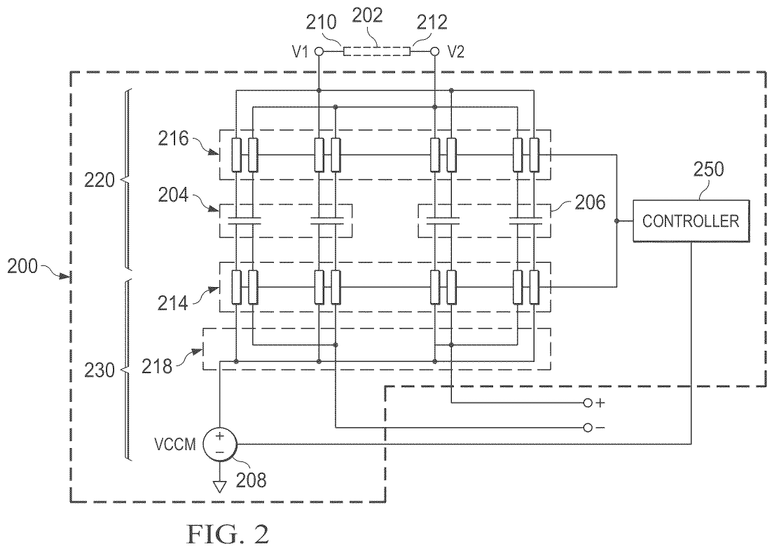

FIG. 2 is a schematic diagram of an operative coupling 200 in accordance with one or more examples. Operative coupling 200 is a non-limiting example of operative coupling 106 of FIG. 1.

Capacitors may be utilized to pass charge because they are passive devices and so do not utilize constant current to operate. Further, the operative coupling 200 does not use current to bias the circuit. Accordingly, dq/dt (change in charge/change in time) via operative coupling 200 may be smaller than typical amplifier inputs and topologies.

Operative coupling 200 may include a first pair of capacitors 204, a second pair of capacitors 206, a controlled common mode voltage source 208, first switches 214, second switches 216, and a controller 250. FIG. 2 depicts an optional resistor 202 for ease of illustration and discussion, the outline of which is depicted using a dashed line. The operative coupling 200 has an input stage 220 isolated from an output stage 230 by the first and second pairs of capacitors 204 and 206. The first and second pairs of capacitors 204 and 206 may provide a galvanic isolation barrier. The input stage 220 includes the second switches 216, which are high voltage domain switches. The output stage 230 includes the first switches 214, which are low voltage domain switches.

First pair of capacitors 204 is switchably coupled between a negative input terminal of a differential amplification circuit and resistor 202, which negative input terminal may also be referred to herein as “first input terminal” Second pair of capacitors 206 is switchably coupled between a positive input terminal of the differential amplification circuit and resistor 202, which positive input terminal may also be referred to herein as a “second input terminal.”

Respective ones of first switches 214 are to couple a respective bottom plate of the first pair of capacitors 204 with the negative input terminal of a differential amplification circuit or a positive output of controlled common mode voltage source 208 at a node 218, and to couple the respective bottom plate of second pair of capacitors 206 with the positive input terminal of the differential amplification circuit or the positive output of controlled common mode voltage source 208 at node 218. The return of common mode voltage source 208 is coupled to a common potential, illustrated as ground, without limitation. Respective second switches 216 are to couple a respective top plate of the first and second pairs of capacitors 204, 206 with a first end 210 of resistor 202 or a second end 212 of resistor 202. Examples of switches include, but are not limited to, Silicon Carbide (SiC) devices and Insulated-Gate Bipolar Transistors (IGBT) devices.

Controlled common mode voltage source 208 provides a controlled common mode voltage (VCCM) to node 218. Node 218 is switchably coupled to respective bottom plates of first pair of capacitors 204 and second pair of capacitors 206 via respective first switches 214. When one or more capacitors of first pair of capacitors 204 and second pair of capacitors 206 are in an integrating phase, they integrate voltage VCCM together with the differential voltage signal component and transfer the differential voltage signal component and VCCM together during a transfer phase, as further described below. Any voltage source for reliably providing a controlled voltage level may be utilized as controlled common mode voltage source 208.

A controller 250 may control the switches 214 and 216, the node 218, and the common mode voltage source 208.

First switches 214 and second switches 216 receive and operate responsive to control signals (control signal not depicted) from controller 250 that selectively turn ON or turn OFF respective ones of first switches 214 and second switches 216. When the respective switches of first switches 214 and second switches 216 are ON they transfer current, and when they are OFF they do not transfer current or transfer negligible current.

When first switches 214 and second switches 216 are alternately turned ON and OFF in a specific manner, respective capacitors of first pair of capacitors 204 and second pair of capacitors 206 alternate between integration and transfer in a complimentary and commutating manner. When first pair of capacitors 204 and second pair of capacitors 206 alternate between integration and transfer at a sufficiently high frequency (e.g., substantially 100 megahertz (MHz) or higher, without limitation), an output signal is generated and continuously applied to the positive and negative input terminals of a differential amplification circuit—i.e., the output signal of operative coupling 200 maintains fidelity with the positive and negative input terminals of the differential amplification circuit.

Referring again to FIG. 1, the amplitude of the output signal of operative coupling 106 is, generally, proportional to the voltage level of the differential voltage signal component. In one example, the amplitude of the output signal 108 of operative coupling 106 may be double the amplitude of the voltage level across resistor 102. Referring to FIG. 25 the first pair of capacitors 204 and second pair of capacitors 206 may alternate between integration and transfer at a frequency high enough to charge one set of capacitors and also high enough to pass charge of the alternating set to the input. Fidelity may be improved when first switches 214 and second switches 216 operate at higher frequencies so that the first pair of capacitors 204 and second pair of capacitors 206 alternate at such higher frequencies.

In one or more examples, operative coupling 200 operates as an alternating current (AC) voltage short circuit and a direct current (DC) voltage isolator in response to operation of first pair of capacitors 204 and second pair of capacitors 206 in a specific manner. Common mode voltage is a DC voltage and (absent outside influences) does not change (or negligibly changes) and there is no AC common mode voltage to store across the capacitor, thus the common mode voltage is not transferred as an input voltage, thereby providing a DC voltage isolation.

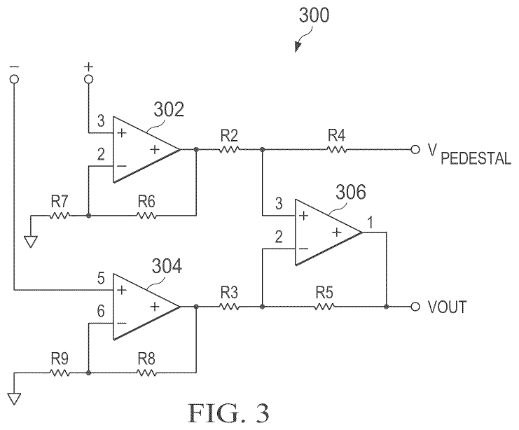

FIG. 3 is a diagram depicting a differential amplification circuit 300 in accordance with one or more examples. Differential amplification circuit 300 is a non-limiting example of differential amplification circuit 104 of FIG. 1.

Differential amplification circuit 300 includes a first differential amplifier 302, a second differential amplifier 304, and a third differential amplifier 306. Respective positive input terminals of first differential amplifier 302 and second differential amplifier 304 may be coupled to the respective first (positive) and second (negative) input terminals of operative coupling 106 or operative coupling 200 (see FIG. 2). Respective negative input terminals of first and second differential amplifiers 302 and 304 are coupled to internal nodes of respective resistive voltage divider circuits (including resistors R6/R7 for first differential amplifier 302, and R8/R9 for second differential amplifier 304) respectively coupled between ground, or other common potential, and respective outputs of first differential amplifier 302 and second differential amplifier 304. Utilization of the resistive voltage divider circuits is optional to divide the gain and increase the speed of first differential amplifier 302 and second differential amplifier 304. An output of first differential amplifier 302 is coupled to a positive input terminal of third differential amplifier 306 via resistor R2 and an output of second differential amplifier 304 is coupled to a negative input terminal of third differential amplifier 306 via resistor R3. The positive input terminal of third differential amplifier 306 is further coupled to provide a pedestal voltage via resistor R4. The pedestal voltage may be utilized to set the output voltage from which to reference (above or below) positive or negative differential signal swings. The negative input terminal of third differential amplifier 306 is further coupled to an output terminal of differential amplification circuit 300 via resistor R5, which output terminal is coupled to the output of third differential amplifier 306. The number of resistors utilized in differential amplification circuit 300 is for example and does not limit the scope of the disclosure in any way.

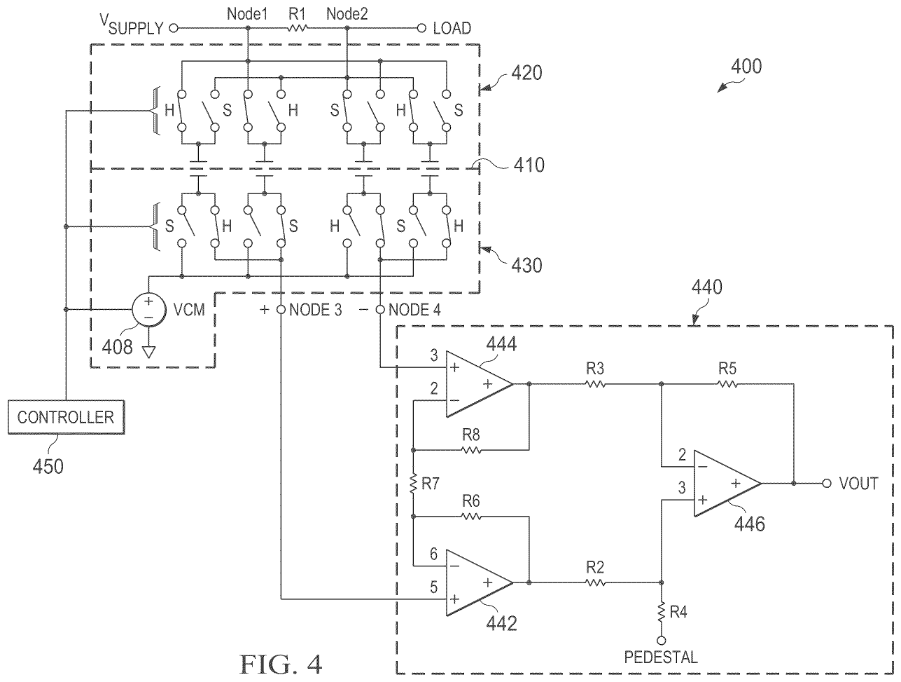

FIG. 4 shows a circuit diagram of an isolation amplifier circuit 400 for a monolithic integrated circuit. The isolation amplifier circuit 400 comprises an operative coupling 410 and a differential amplification circuit 440. The operative coupling 410 has an input stage 420 isolated from an output stage 430 by capacitors. The isolation amplifier circuit 400 may be used for current sensing, where small input signals produce high gain. The isolation amplifier circuit 400 may also be used as an isolation amplifier, where large input signals produce low gain.

The isolation amplifier circuit 400 has input terminals at Node 1 and Node 2 to input an analog signal. The analog signal may be supplied by V_{SUPPLY} and LOAD connected by a resistor R1, where Node 1 is between V_{SUPPLY} and a first terminal of resistor R1, and Node 2 is between a second terminal of resistor R1 and LOAD.

The isolation amplifier circuit 400 may use the pedestal voltage PEDESTAL as a reference, relative to positive or negative differential signal swings, from which to set the output voltage VOUT. The differential amplification circuit 440 may have three differential amplifiers 442, 444, and 446. Respective positive input terminals of first differential amplifier 442 and second differential amplifier 444 may be coupled to the respective first (positive) and second (negative) output terminals of operative coupling 410 at Node 3 and Node 4, respectively. Respective negative input terminals of first and second differential amplifiers 442 and 444 are coupled to internal nodes of respective resistive voltage divider circuits (including resistors R6/R7 for first differential amplifier 442, and R8/R7 for second differential amplifier 444, with resistor R7 shared between first differential amplifier 442 and second differential amplifier 444). An output of first differential amplifier 442 is coupled to a positive input terminal of third differential amplifier 446 via resistor R2 and an output of second differential amplifier 444 is coupled to a negative input terminal of third differential amplifier 446 via resistor R3. The positive input terminal of third differential amplifier 446 is further coupled to a pedestal voltage via resistor R4.

The isolation amplifier circuit 400 shown in FIG. 4 senses the current which is represented by the voltage drop across resistor R1 as it travels between V_{SUPPLY} and LOAD. Voltage common mode (VCM) is the voltage of V_{SUPPLY} that may be satisfying the load and the amount of current flowing through resistor R1 may be detected by the voltage drop across resistor R1, which voltage drop may be small in relation to the voltage of V_{SUPPLY}.

Whether the current is going from V_{SUPPLY} to LOAD or from LOAD to V_{SUPPLY} may be detected by whether the VOUT voltage is above or below the PEDESTAL voltage. If the voltage between Node 3 and Node 4 of the first and second differential amplifiers 442 and 444 are a differential negative value (Node 3−Node 4=negative voltage), then voltage VOUT will be higher than PEDESTAL voltage. Likewise, if the difference between Node 3 and Node 4 of the first and second differential amplifiers 442 and 444 is positive (Node 3−Node 4=positive voltage), then voltage VOUT will be lower than the PEDESTAL voltage. The isolation amplifier circuit 400 is bidirectional. The isolation amplifier circuit 400 detects whether the voltage VOUT is above or below the reference voltage, called PEDESTAL, by getting positive and negative differences on these nodes (Node 3−Node 4) when the input signal (current) goes in both directions, respectively. The isolation amplifier circuit 400 provides this bidirectional detection through the nature of the amplifier's setup. If VOUT voltage is above the PEDESTAL voltage, then the current is determined to be going from V_{SUPPLY} to LOAD. If VOUT voltage is below the PEDESTAL voltage, then the current is determined to be going from LOAD to V_{SUPPLY}.

FIG. 4 shows the operative coupling 410 has an input stage 420 isolated from an output stage 430 by capacitors. The input stage 420 may have an integrated power supply via the common mode voltage source VCM 408 through high voltage capacitors to provide high voltage isolated input. There may be no data or power converter. Isolation may be inherent, which lowers cost of production, provides a smaller solution, and operates more efficiently. The input stage 420 may be a set of high voltage domain switches. The output stage 430 may be a set of low voltage domain switches. The circuitry assumes power is supplied to drive the differential amplifiers 442 444 446, and this same power supply for the differential amplifiers 442 444 446 may be used to create a VCM reference voltage via the common mode voltage source 408. The Vsupply may not be used to drive or power a circuit to send the signal, but merely provides a passive supply across Node 1 and Node 2 to the load. There is no real power from the common mode voltage source 408 except to replace the signal power lost or gained (very slight) every other cycle. The common mode voltage source 408 is used to set the reference value in which the signal either climbs above or below every other cycle depending on the input differential signal at Node 1 and Node 2.

A controller 450 may control the high voltage domain switches of the input stage 420, the low voltage domain switches of the output stage 430, and sets the level of the common mode voltage source 408. A high voltage capacitor may be implemented as a level shifter for isolation of the control signal for the high voltage domain switches of the input stage 420 relative to the control signal for the low voltage domain switches of the output stage 430.

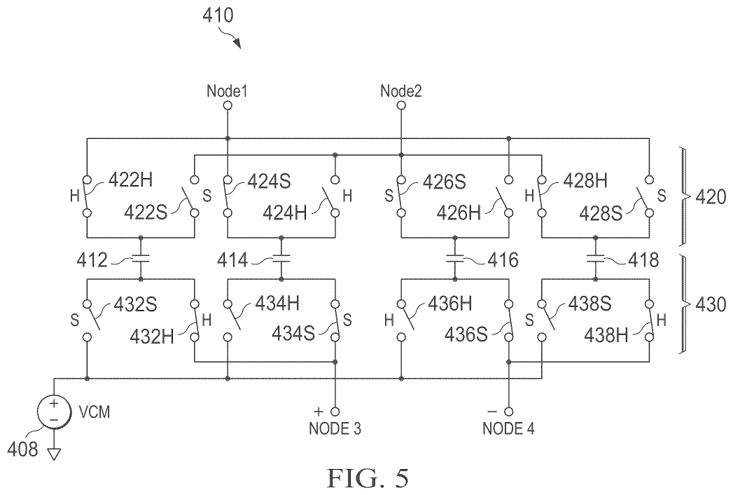

FIG. 5 shows an enlarged view of the operative coupling 410 shown in FIG. 4. The operative coupling 410 has four capacitors 412, 414, 416, and 418, an input stage 420 having a set of high voltage domain switches, and an output stage 430 having a set of low voltage domain switches. The switches of the input and output stages 420 and 430 may be two different voltage domains and may be synchronized and operating at a set frequency, for example 100 megahertz (MHz) or higher, without limitation. In some aspects, the switches may operate at lower sampling frequencies for lower offset for example (longer charging time, larger caps are used). It may be simplified if only one type of transmission gate is used for the switches, for example PMOS, but they may be different. The switches of the input stage 420 may reach the V_{SUPPLY} voltage (OFF) and V_{SUPPLY} voltage (ON). The high voltage domain switches of the input stage 420 and the low voltage domain switches of the output stage 430 may be synchronously operated so that a switch is the same as the common mode voltage source 408 when OFF and at least three volts lower than the common mode voltage source 408 when ON. The voltage gate source (VSG) of a positive channel metal-oxide semiconductor (PMOS) device may be Vsupply=OFF and Vsupply−3V=ON. In other words, the switch is OFF and the switch is ON.

FIG. 5 shows the input stage 420 includes high voltage domain switches 422H, 422S, 424S, 424H, 426S, 426H, 428H, and 428S. The output stage 430 includes low voltage domain switches 432S, 432H, 434H, 434S, 436H, 436S, 438S, and 438H. A first end of high voltage domain switches 422H, 424S, 426S, and 428H are connected in parallel to Node 1. A first end of high voltage domain switches 422S, 424H, 426H, and 428S are connected in parallel to Node 2. A first end of low voltage domain switches 432S, 434H, 436H, and 438S are connected in parallel to the positive output of common mode voltage source 408, i.e. voltage VCM. A first end of low voltage domain switches 432H and 434S are connected in parallel to Node 3. A first end of low voltage domain switches 436S, and 438H are connected in parallel to Node 4. A second end of high voltage domain switches 422H and 422S are connected to a first plate of capacitor 412, and a second end of low voltage domain switches 432S and 432H are connected to a second plate of capacitor 412. A second end of high voltage domain switches 424S and 424H are connected to a first plate of capacitor 414, and a second end of low voltage domain switches 434H and 434S are connected to a second plate of capacitor 414. A second end of high voltage domain switches 426S and 426H are connected to a first plate of capacitor 416, and a second end of low voltage domain switches 436H and 436S are connected to a second plate capacitor 416. A second end of high voltage domain switches 428H and 428S are connected to a first plate of capacitor 418, and a second end of low voltage domain switches 438S and 438H are connected to a second plate of capacitor 418.

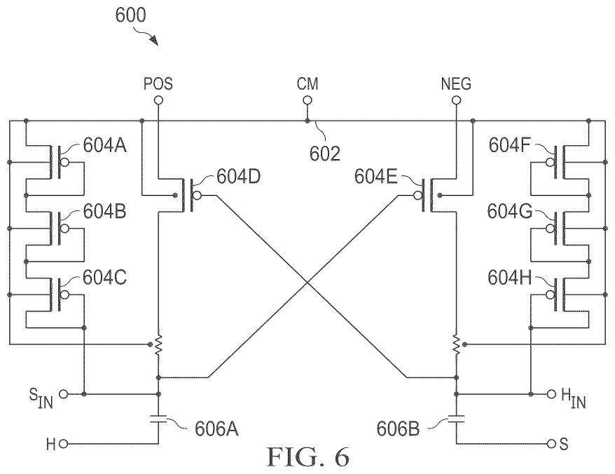

The isolation provided by operative coupling 410 may be galvanic through the capacitors 412, 414, 416, and 418. The topology of the operative coupling 410 may transfer a differential voltage signal component hovering within a range of a common mode voltage source 408, to a low voltage domain, wherein the transfer may be done via capacitor coupling. For example, a signal component at +/−1000 V may be transferred down to +/−500 V, or +/−100 V, or any voltage less than +/−1000 V, without limitation. The low voltage domain switches 432S, 432H, 434H, 434S, 436H, 436S, 438S, and 438H may be controlled and the amplifier input side of the capacitors may be driven by low voltage inverters to pump or pull voltage to drive input gates. The capacitors for level shifting (see FIG. 6) may be charged by low voltage inverters (not shown) that pump or pull voltage to drive the high voltage domain switches 422S, 422H, 424H, 424S, 426H, 426S, 428S, and 428H. In particular, the input switches at 422H, 422S, 424S, 424H, 426S, 426H, 428H, and 428S are low voltage switches localized at a high voltage. And the output switches 432H, 432S, 434S, 434H, 436S, 436H, 438H, and 438S are low voltage switches localized at a low voltage and isolated by 412, 414, 416, 418 HV capacitors.

The high voltage capacitors provide the galvanic isolation function. Isolation may be accomplished in the analog signal path without an analog-to-digital conversion on the input side or a complimentary digital-to-analog conversion on the output side of the isolation circuit. Because isolated power is not supplied, transformers may not be required as part of the circuit. Whereas, in prior circuits, isolated power was provided, and so transformers were part of the prior circuits. With high voltage capacitors in the analog signal path for isolation, the signal may remain analog from the input to the output.

Referring to FIG. 6, depicted is a schematic diagram of a high-voltage level shifter 600 having very small signal propagation time delay. The switches in the input stage 420 and the output stage 430 may be in two different voltage domains, and may be synchronized by operating at a frequency, for example 100 MHz (see FIG. 5). The high voltage domain switches 422H, 422S, 424S, 424H, 426S, 426H, 428H, and 428S of the input stage 420 may reach the Vsupply voltage (OFF) and Vsupply−3V (ON). The high-voltage level shifter shown in FIG. 6 may provide fast isolating, charge pumping level shifting to allow the switches of the input stage 420 to reach (OFF) and (ON). Level shifting may be by pumping the values to the common mode CM 602 or (CM-3V) (3 VGS clamp) via capacitors 606A and 606B. According to one aspect, one type of transmission gate may be used (PMOS), for example transistors 604A-604H may be PMOS transistors.

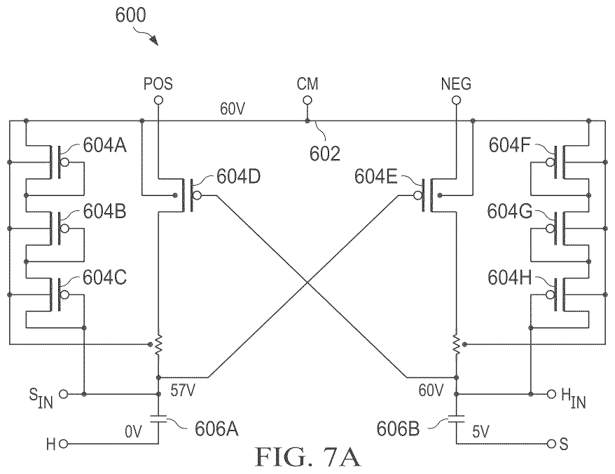

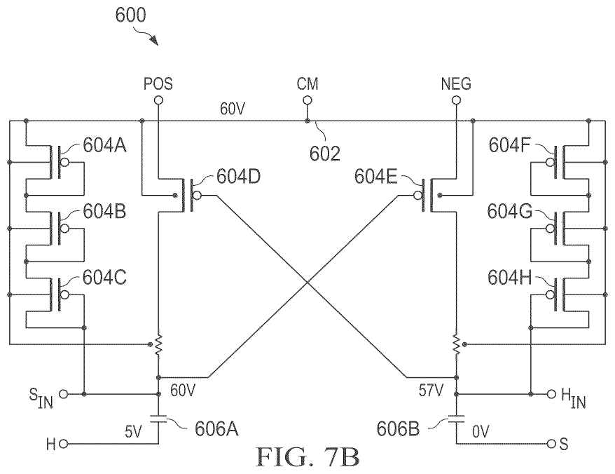

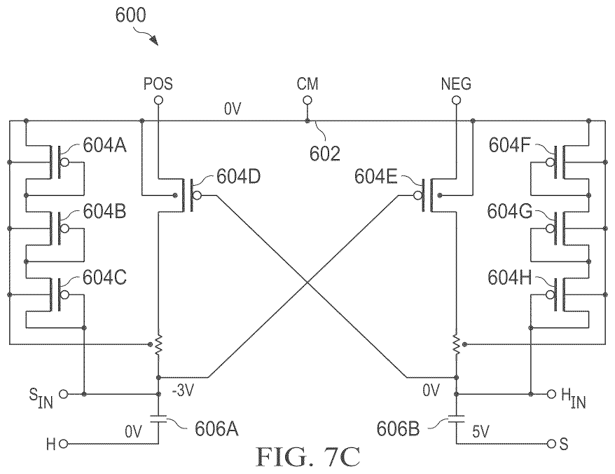

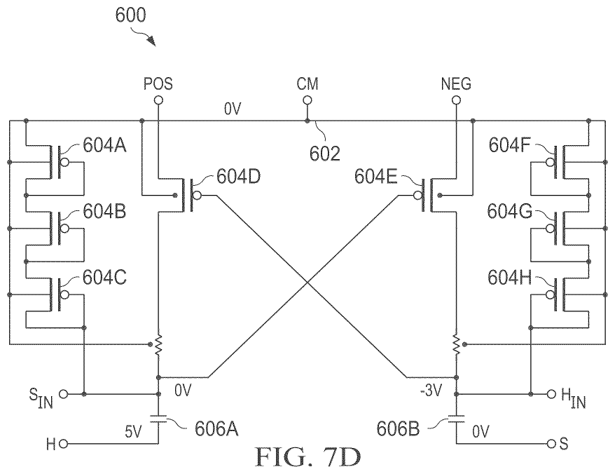

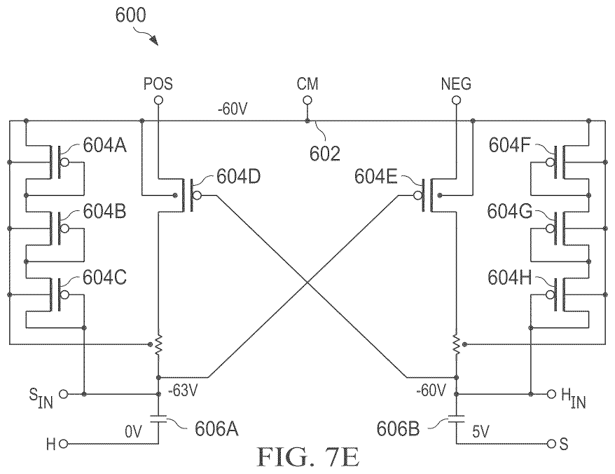

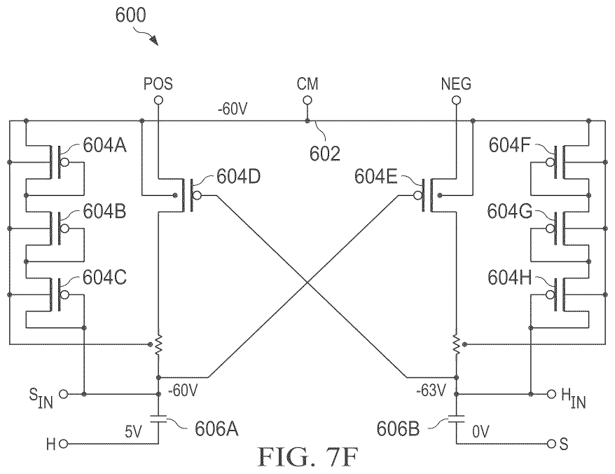

Referring to FIG. 7A-7F, depicted are schematic block diagrams of the high-voltage level shifter shown in FIG. 6, wherein generated clock signals drive the input switches at their relative common modes. FIG. 7A shows that a 60V common mode, Sᵢₙ is 57V, and Hᵢₙ is 60V provides H is 0V and S is 5V. FIG. 7B shows that a 60V common mode, Sᵢₙ is 60V, and Hᵢₙ is 57V provides H is 5V and S is 0V. FIG. 7C shows that a 0V common mode, Sᵢₙ is −3V, and Hᵢₙ is 0V provides H is 0V and S is 5V. FIG. 7D shows that a 0V common mode, Sᵢₙ is 0V, and Hᵢₙ is −3V provides H is 5V and S is 0V. FIG. 7E shows that a −60V common mode, Sᵢₙ is −63V, and Hᵢₙ is −60V provides H is 0V and S is 5V. FIG. 7F shows that a −60V common mode, Sᵢₙ is −60V, and Hᵢₙ is −63V provides H is 5V and S is 0V.

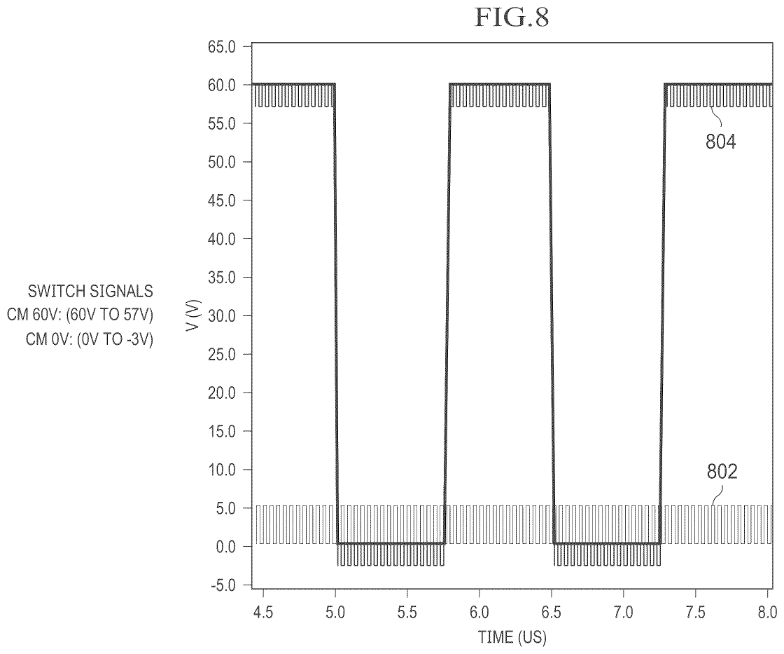

FIG. 8 shows a graph of input and output voltages across time, illustrating the waveform of the control signals used to drive the switches of an operative coupling. The graph indicates: the high voltage capacitors provide isolation; the capacitors provide almost instant voltage transfer (they are only transferring the differential voltage signal component); and the capacitors provide negative and positive transfer (i.e. the transfer is bidirectional—the isolation amplifier circuit detects whether the voltage output is above or below the reference common mode voltage (VCM). FIG. 8 demonstrates two common mode examples, one at 60V, and another at 0V. Waveform 802 is a constant 0V to 5V clock. Waveform 804 is the result of the level shift showing the generated clock signal to drive the input switches at their relative common modes. At 60V common mode the switch ON would be 57V and switch OFF would be 60V. At 0V common mode the switch ON would be −3V and the switch OFF would be 0V.

A monolithic integrated circuit may be smaller in size because there may be fewer external components and occupies less board area. The device may have lower power loss in a shunt, wherein the shunt may create a voltage drop as current is run to the load. The device may have lower IC power and may include a power saving shutdown pin. The device may be more accurate and may cost less to produce than isolation amplifiers that provide a power supply to the isolation side of the circuit, that convert analog to digital signals, or that use optocouplers to directly couple analog signals. The device may provide high voltage shunt current sensing, e.g., +/−1000 volts, including bipolar common-mode voltage (CMV). The device may provide sensing with galvanic isolation from measuring equipment. The device may break ground loops. The device may be implemented in high voltage systems including such things as electric vehicles and solar panel arrays. The device may be used for industrial test and measurement where isolated sensing is often a design parameter.

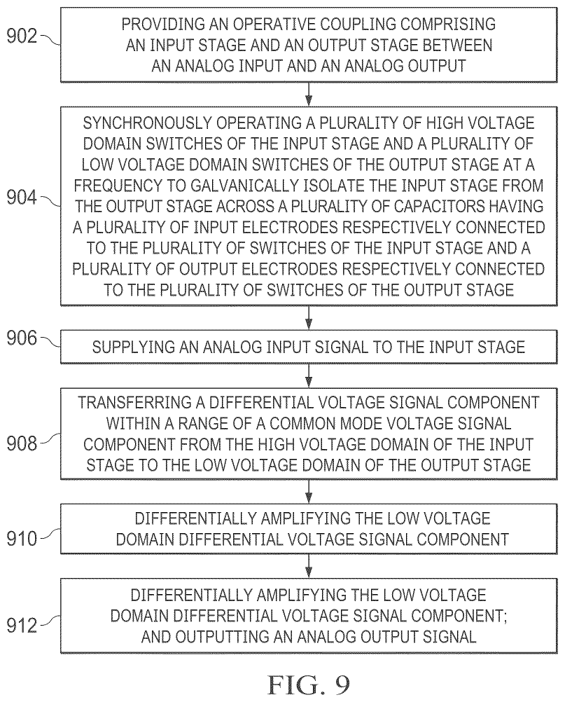

FIG. 9 shows a flow chart of a method for switching capacitors to galvanically isolate and amplify analog signals via transferred differential voltage signal components. The method may provide isolation amplification of an analog signal without analog-to-digital conversion of the signal and without isolated power being supplied to a remote side or input stage of a circuit. An operative coupling is provided 902 comprising an input stage and an output stage between an analog input and an analog output. A plurality of high voltage domain switches of the input stage and a plurality of low voltage domain switches of the output stage are synchronously operated 904 at a frequency to galvanically isolate the input stage from the output stage across a plurality of capacitors having a plurality of input plates respectively connected to the plurality of switches of the input stage and a plurality of output plates respectively connected to the plurality of switches of the output stage. An analog input signal is supplied 906 to the input stage. A differential voltage signal component within a range (e.g. +/−1000 V) of a common mode voltage signal component is transferred 908 from the high voltage domain of the input stage to the low voltage domain of the output stage. The low voltage domain differential voltage signal component is differentially amplified 910. An analog output signal is output 912.

Although examples have been described above, other variations and examples may be made from this disclosure without departing from the spirit and scope of these disclosed examples.

1. A method comprising:
providing an operative coupling comprising an input stage and an output stage between an analog input and an analog output;
synchronously operating a plurality of high voltage domain switches of the input stage and a plurality of low voltage domain switches of the output stage at a frequency to galvanically isolate the input stage from the output stage across a plurality of capacitors having a plurality of input plates respectively connected to the plurality of switches of the input stage and a plurality of output plates respectively connected to the plurality of switches of the output stage;
supplying an analog input signal to the input stage;
transferring a differential voltage signal component within a range of a common mode voltage signal component from the high voltage domain of the input stage to the low voltage domain of the output stage;
differentially amplifying the low voltage domain differential voltage signal component; and
outputting an analog output signal.

2. The method as in claim 1, wherein the frequency is greater than or equal to 100 MHz.

3. The method as in claim 1, wherein the common mode voltage signal component is +/−1000 volts.

4. The method as in claim 1, wherein the common mode voltage signal component is +/−100 volts.

5. The method as in claim 1, wherein the range of a common mode voltage signal component is +/−100 volts.

6. The method as in claim 1, wherein synchronously operating comprises charging the plurality of capacitors.

7. The method as in claim 1, wherein synchronously operating the plurality of high voltage domain switches of the input stage and a plurality of low voltage domain switches of the output stage so that a respective one of the plurality of switches is the common mode voltage when OFF and at least three volts lower than the common mode voltage when ON.

8. The method as claimed in claim 1, wherein the analog input signal comprises a voltage.

9. The method as claimed in claim 1, wherein the output signal is relative to a reference signal, wherein positive and negative output signals indicate direction of current.

10. A monolithic integrated circuit comprising:
input terminals to receive an analog input signal;
an operative coupling comprising:
an input stage coupled to the input terminals and comprising a plurality of high voltage domain switches;
an output stage comprising a plurality of low voltage domain switches and a voltage common mode power source;
a plurality of capacitors having a plurality of input plates respectively connected to the plurality of high voltage domain switches and a plurality of output plates respectively connected to the plurality of low voltage domain switches; and
a controller to synchronously operate the plurality of input switches and the plurality of output switches at a frequency to charge respective ones of the plurality of capacitors;
wherein the operative coupling is to transfer a differential voltage signal component from a high voltage domain to a low voltage domain;
a differential amplification circuit coupled to the output stage of the operative coupling to amplify the transferred differential voltage signal component; and
output terminals coupled to the differential amplification circuit to output an analog output signal.

11. The monolithic integrated circuit as in claim 10, wherein the frequency is greater than or equal to 100 MHz.

12. The monolithic integrated circuit as in claim 10, wherein the controller is to synchronously operate the plurality of high voltage domain switches of the input stage and a plurality of low voltage domain switches of the output stage so that a respective one of the plurality of switches is the common mode voltage when OFF and at least three volts lower than the common mode voltage when ON.

13. A monolithic integrated circuit comprising:
input terminals to receive an analog input signal;
an operative coupling comprising:
an input stage coupled to the input terminals and comprising a plurality of high voltage domain switches;
an output stage comprising a plurality of low voltage domain switches and a voltage common mode power source;
a plurality of capacitors having a plurality of input plates respectively connected to the plurality of high voltage domain switches and a plurality of output plates respectively connected to the plurality of low voltage domain switches; and
a controller to synchronously operate the plurality of high voltage domain switches and the plurality of low voltage domain switches at a frequency to galvanically isolate the input stage from the output stage and to transfer a differential voltage signal component within a range of a common mode voltage signal component from the high voltage domain to the low voltage domain;
a differential amplification circuit coupled to the output stage of the operative coupling; and
output terminals coupled to the differential amplification circuit to output an analog output signal.

14. The monolithic integrated circuit as in claim 13, wherein frequency is greater than or equal to 100 MHz.

15. The monolithic integrated circuit as in claim 13, wherein the common mode voltage signal component is +/−1000 volts.

16. The monolithic integrated circuit as in claim 13, wherein the common mode voltage signal component is +/−100 volts.

17. The monolithic integrated circuit as in claim 13, wherein the range of a common mode voltage signal component is +/−100 volts.

18. The monolithic integrated circuit as in claim 13, wherein the controller is to charge the plurality of capacitors.

19. The monolithic integrated circuit as in claim 18, wherein the controller to synchronously operate the plurality of high voltage domain switches and the plurality of low voltage domain switches comprises a respective one of the switches to be the common mode voltage when OFF and at least three volts lower than the common mode voltage when ON.

20. The monolithic integrated circuit as in claim 13, wherein the output signal is relative to a reference signal, wherein positive and negative output signals indicate direction of current.
